(19) United States
(12) Patent Application Publication
(10) Pub. No.: US 2011/0030769 A1
(43) Pub. Date: Feb. 10, 2011

(54) SOLAR CELL AND METHOD FOR MANUFACTURING THE SAME

(75) Inventor: Czang-Ho LEE, Hwasung-si (KR)

Correspondence Address: CANTOR COLBURN LLP, 20 Church Street, 22nd Floor, Hartford, CT, 06103, US

(73) Assignee: SAMSUNG ELECTRONICS CO., LTD., Suwon-si (KR)

(21) Appl. No.: 12/828,804

(22) Filed: Jul. 1, 2010

(30) Foreign Application Priority Data
Aug. 10, 2009 (KR) 10-2009-0073482

(51) Int. Cl. H01L 31/0288; H01L 31/0368; H01L 31/18

(52) U.S. Cl. 136/255; 136/258; 438/97; 257/E31.043

(57) ABSTRACT

A solar cell including an insulation substrate, a buffer layer disposed on the insulation substrate, a first electrode disposed on the buffer layer, a first polycrystalline semiconductor layer disposed on the first electrode and including first impurities, a photo-absorptive layer disposed on the first polycrystalline semiconductor layer, a second semiconductor layer disposed on the photo-absorptive layer and including second impurities, and a second electrode disposed on the second semiconductor layer.

This application claims priority to Korean Patent Application No. 10-2009-0073482 filed on Aug. 10, 2009, and all the benefits accruing therefrom under 35 U.S.C. §119, the entire contents of which are incorporated herein by reference.

### BACKGROUND OF THE INVENTION

1. Field of the Invention

This disclosure relates to a solar cell and a method of manufacturing the same.

2. Description of the Related Art

A solar cell is a photoelectric conversion device transforming solar energy into electrical energy, and has gained much attention as an infinite but pollution-free next generation energy source.

A solar cell includes p-type and n-type semiconductors. The solar cell produces electrical energy by transferring electrons and holes to the n-type and p-type semiconductors, respectively, and then collecting the electrons and holes in each electrode, when an electron-hole pair (“EHP”) is produced by solar light energy absorbed in a photoactive layer inside the semiconductors.

Further, a silicon solar cell may be classified into a mono-crystalline or polycrystalline silicon solar cell based on a crystalline silicon wafer, and a thin film silicon solar cell based on a glass substrate.

The crystalline silicon wafer has merits such that the degeneration is less even in the case of applying the crystalline silicon wafer to a solar cell, and several micrometers (μm) is substantially enough thickness of silicon for generating electricity by absorbing solar light. However, the cost of manufacturing a silicon wafer is high.

The thin film silicon solar cell may be broadly classified into an amorphous silicon solar cell, a micro-crystalline silicon solar cell, and a polycrystalline silicon solar cell. The amorphous silicon solar cell has demerits of degenerating light characteristics depending upon passage of time, although the amorphous silicon solar cell shows high photo-absorption in the visible light region and is formed with a relatively thin thickness.

### BRIEF SUMMARY OF THE INVENTION

An exemplary embodiment of the invention provides a solar cell and a method of manufacturing the same. Another embodiment of the invention provides a solar cell including a thin film of polycrystalline silicon that is capable of decreasing degradation of the solar cell and the manufacturing cost, and that can be mass-produced, and a method of manufacturing the same.

An exemplary embodiment of the provides a solar cell including an insulation substrate, a buffer layer disposed on the insulation substrate, a first electrode disposed on the buffer layer, a first polycrystalline semiconductor layer disposed on the first electrode and including a first impurity, a photo-absorptive layer disposed on the first polycrystalline semiconductor layer, a second semiconductor layer disposed on the photo-absorptive layer and including a second impurity, and a second electrode disposed on the second semiconductor layer.

The first polycrystalline semiconductor layer may be a polycrystalline silicon doped with the first impurity at a high concentration, and the photo-absorptive layer may be doped with the first impurity at a low concentration.

The second semiconductor layer may be a polycrystalline silicon doped with the second impurity.

The second semiconductor layer may be an amorphous silicon including the second impurity.

At least one of the first electrode and the second electrode may include a transparent conductive material.

The second electrode may include a transparent conductive material, and the solar cell may further include a metal layer disposed between the buffer layer and the first electrode.

The metal layer may include chromium (Cr), tungsten (W), molybdenum (Mo), and the like.

The transparent conductive material may include zinc oxide, indium tin oxide (“ITO”) or indium zinc oxide (“IZO”).

The metal layer or the first electrode may include surface structures including prominences and depressions, or the second electrode may include an antireflection treatment.

The second electrode may include an opaque metal.

The opaque metal may include chromium, tungsten, molybdenum, silver, or aluminum.

The second electrode may include surface structures including protrusions and depressions, or the buffer layer may include an antireflection treatment.

The solar cell may further include an auxiliary photo-absorptive layer between the second semiconductor layer and the second electrode, and the auxiliary photo-absorptive layer may include an amorphous silicon layer including the first impurity, a non-doped amorphous silicon layer, and an amorphous silicon layer including the second impurity.

The buffer layer may include silicon oxide or silicon nitride. Another exemplary embodiment of the invention provides a method of manufacturing unit cells of a solar cell, the method including providing a buffer layer on an insulation substrate, providing a first electrode on the buffer layer, providing an amorphous semiconductor on the first electrode, crystallizing the amorphous semiconductor, and providing a second electrode on the crystallized semiconductor.

The method may further include hydrogenising after crystallizing the amorphous semiconductor.

The providing a first electrode includes scribing the first electrode with a laser to provide a one side electrode for forming an independent unit cell. The amorphous semiconductor formed while providing the amorphous semiconductor may be contacted with the area of the first electrode where the first electrode is scribed with a laser.

The method may further include scribing the crystallized polycrystalline semiconductor with a laser to expose the first electrode. The second electrode may be electrically contacted with the exposed area of the first electrode while providing the second electrode.

After providing the second electrode, the method may further include scribing the second electrode and the crystallized polycrystalline semiconductor with a laser to electrically separate adjacent unit cells of the solar cell from each other.

The second electrode may be formed of a transparent conductive material. The method may further include providing a metal layer between the buffer layer and the first electrode. The providing a second electrode may further include subjecting the second electrode with an antireflection treatment, or the providing a metal layer of the first electrode may include treating the metal layer or the first electrode with a surface texturing treatment to provide various surface structures including protrusions and depressions.

The second electrode may be formed of an opaque metal. The providing a second electrode may include subjecting the second electrode to a surface texturing treatment to provide various surface structures including protrusions and depressions. The providing a buffer layer may include subjecting the buffer layer to an antireflection treatment.

The providing an amorphous semiconductor on the first electrode may include providing a first amorphous silicon including a first impurity on the first electrode, providing a non-doped second amorphous silicon on the first amorphous silicon, and providing a third amorphous silicon including a second impurity on the second amorphous silicon

The providing an amorphous semiconductor on the first electrode may include providing a first amorphous silicon including a first impurity on the first electrode, crystallizing the first amorphous silicon to provide a seed layer, and developing the non-doped second silicon in accordance with an epitaxy method to provide a polycrystalline semiconductor.

After the crystallizing the amorphous semiconductor, the method may further include laminating the third amorphous silicon including a second impurity on the crystallized semiconductor.

After crystallizing the amorphous semiconductor, the method may further include providing an auxiliary photo-absorptive layer on the crystallized semiconductor. The providing an auxiliary photo-absorptive layer may include providing a fourth amorphous silicon layer including a first impurity on the crystallized semiconductor, providing a non-doped fifth amorphous silicon layer on the fourth amorphous silicon layer, and providing a sixth amorphous silicon layer including a second impurity on the fifth amorphous silicon layer.

### BRIEF DESCRIPTION OF THE DRAWINGS

The above and other advantages and features of the invention will become more apparent by describing in further detail exemplary embodiments thereof, with reference to the accompanying drawings, in which:

FIG. 1 is a cross-sectional view of an exemplary embodiment of a unit cell of a solar cell, according to the invention.

FIGS. 2 to 8 are cross-sectional views showing sequential processes of an exemplary embodiment of manufacturing a solar cell module, including the unit cell shown in FIG. 1.

FIG. 9 is a cross-sectional view of another exemplary embodiment of a unit cell of a solar cell, according to the invention.

FIGS. 10 to 17 are cross-sectional views showing sequential processes of another exemplary embodiment of manufacturing a solar cell module, including the unit cell shown in FIG. 9.

FIG. 18 is a cross-sectional view of another exemplary embodiment of a solar cell module, according to the invention.

FIG. 19 is a cross-sectional view of another exemplary embodiment of a solar cell module, according to the invention.

FIG. 20 is a cross-sectional view of another exemplary embodiment of a unit solar cell of a solar cell module, according to the invention.

### DETAILED DESCRIPTION OF THE INVENTION

Exemplary embodiments of the invention will hereinafter be described in detail referring to the following accompanied drawings and can be easily performed by those who have common knowledge in the related field. However, these embodiments are only exemplary, and this disclosure is not limited thereto.

In the drawings, the thickness of layers, films, panels, regions, etc., are exaggerated for clarity. Like reference numerals designate like elements throughout the specification. It will be understood that when an element such as a layer, film, region, or substrate is referred to as being “on” or “connected to” another element, it can be directly on or connected to the other element or intervening elements may also be present. In contrast, when an element is referred to as being “directly on” or “directly connected to” another element, there are no intervening elements present. As used herein, the term “and/or” includes any and all combinations of one or more of the associated listed items.

It will be understood that, although the terms first, second, third, etc., may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the invention.

Spatially relative terms, such as “lower,” “upper” and the like, may be used herein for ease of description to describe the relationship of one element or feature to another element(s) or feature(s) as illustrated in the figures. It will be understood that the spatially relative terms are intended to encompass different orientations of the device in use or operation, in addition to the orientation depicted in the figures. For example, if the device in the figures is turned over, elements described as “lower” relative to other elements or features would then be oriented “upper” relative to the other elements or features. Thus, the exemplary term “lower” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of the invention. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Embodiments of the invention are described herein with reference to cross-section illustrations that are schematic illustrations of idealized embodiments (and intermediate structures) of the invention. As such, variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing.

For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the invention.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

All methods described herein can be performed in a suitable order unless otherwise indicated herein or otherwise clearly contradicted by context. The use of any and all examples, or exemplary language (e.g., “such as”), is intended merely to better illustrate the invention and does not pose a limitation on the scope of the invention unless otherwise claimed. No language in the specification should be construed as indicating any non-claimed element as essential to the practice of the invention as used herein.

Hereinafter, the invention will be described in detail with reference to the accompanying drawings.

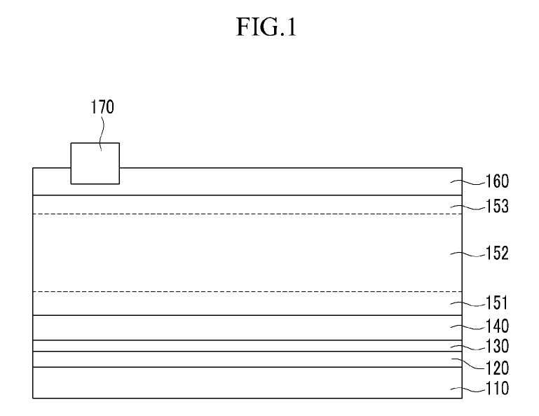

Referring to FIG. 1, a solar cell according to an exemplary embodiment of the invention is described in detail.

FIG. 1 is a cross-sectional view of an exemplary embodiment a unit cell of a solar cell according to the invention.

The solar cell according to the embodiment shown in FIG. 1 generates electrical energy using incident light from an upper side of a substrate 110 (e.g., top of the view in FIG. 1).

Referring to FIG. 1, a unit cell of the solar cell includes a plurality of layers disposed on the substrate 110. The substrate 110 includes an insulating material, such as glass. A silicon oxide (SiO₂) buffer layer 120 is disposed on the glass substrate 110. The buffer layer 120 may include silicon nitride (SiNx) according to an exemplary embodiment. The buffer layer 120 is a layer which prevents the diffusion of impurities from the glass substrate 110, while amorphous silicon is crystallized. In addition, the buffer layer 120 is a layer which decreases heat energy during transfer of heat energy generated by crystallizing the amorphous silicon to the glass substrate 110, so as to reduce damage to the glass substrate 110.

On the buffer layer 120, a metal layer 130 is disposed. The metal layer 130 blocks light, even if the light is incident from a back surface which opposes the upper side of the glass substrate 110. In addition, the metal layer 130 reflects the incident light from an upper surface of the metal layer 130, and returns the reflected light into the polycrystalline silicon layer disposed on the metal layer 130, so as to improve the efficiency of the solar cell.

In an exemplary embodiment, the metal layer 130 may be subjected to a surface texturing treatment to provide various surface structures, such as pyramid structure including prominences and depressions, in order to disperse the incident light from the upper side of the metal layer 130, and to induce the light into a polycrystalline silicon disposed on the metal layer 130. The metal layer 130 may include chromium (Cr), tungsten (W), molybdenum (Mo), or the like.

A first transparent conductive layer 140, such as including transparent zinc oxide (ZnO) having electrical conductivity, is disposed on the metal layer 130. According to an exemplary embodiment of the invention, the first transparent conductive layer 140 includes the zinc oxide (ZnO), but the first transparent conductive layer 140 may includes another transparent material having electrical conductivity in an alternative embodiment.

In an exemplary embodiment, since the metal layer 130 and the first transparent conductive layer 140 effectively form a one-side electrode of the unit cell of the solar cell, a contact to the outside of the solar cell may be electrically and/or physically connected to either the metal layer 130 or the first transparent conductive layer 140 as the one-side electrode.

In addition, the first transparent conductive layer 140 may assist the metal layer 130 in reflecting the incident light from the upper side of the substrate 110. In other words, the first transparent conductive layer 140 may be subjected to a surface texturing treatment on one side surface thereof to provide the various surface structures, such as a pyramid structure including protrusions and depressions, so as to disperse the reflected light to the metal layer 130 and to return the reflected light to the polycrystalline silicon layer disposed on the metal layer 130.

Polycrystalline semiconductors 151, 152, 153 are disposed on the first transparent conductive layer 140. The polycrystalline semiconductors 151, 152, 153 include a first polycrystalline semiconductor layer 151 doped with P-type impurities at a high concentration, a second polycrystalline semiconductor layer 152 doped with P-type impurities at a low concentration, and a third polycrystalline semiconductor layer 153 doped with N-type impurities at a high concentration. The second polycrystalline semiconductor layer 152 functions as a photo-absorptive layer.

An electron or hole generated by absorbing the light from an upper side of a substrate 110, is transferred into the first and third polycrystalline semiconductor layers 151 or 153 to generate electrical energy. In exemplary embodiments, the P-type impurities may be Group III compounds such as boron (B), and the N-type impurities may be Group V compounds such as phosphorus (P).

In an alternative exemplary embodiment, the first polycrystalline semiconductor layer 151 and the third polycrystalline semiconductor layer 153 may be disposed oppositely to the configuration shown in FIG. 1. In the oppositely disposed structure, where the third polycrystalline semiconductor layer 153 includes P-type impurities at a high concentration and the first polycrystalline semiconductor layer 151 includes N-type impurities at a high concentration, the second polycrystalline semiconductor layer 152 may instead be a polycrystalline semiconductor layer doped with N-type impurities at a low concentration.

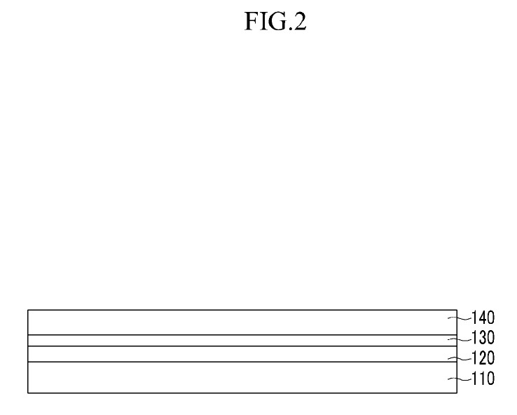

According to the embodiment shown in FIG. 1, the first, second and third polycrystalline semiconductors 151, 152, and 153 are formed without a seed layer. A method of manufacturing the above described structure of the solar cell will be described hereinafter with reference to FIG. 2 to FIG. 8.

A second transparent conductive layer 160 is disposed on an uppermost surface of the first, second and third polycrystalline semiconductors 151, 152, and 153. The second transparent conductive layer 160 functions as a side electrode of the unit cell of the solar cell, as being electrically and physically connected to the metal layer 130 and the first transparent conductive layer 140. In addition, the second transparent conductive layer 160 may be subjected to an antireflection treatment in order to improve the efficiency of the incident light from the upper side of the substrate 110. The second transparent conductive layer 160 includes a transparent conductive material having high electrical conductivity. In an exemplary embodiment, the second transparent conductive layer 160 may include indium tin oxide (“ITO”), ZnO, indium zinc oxide (“IZO”), and so on.

A wire 170 including metal such as silver, is disposed on one region of the second transparent conductive layer 160. The wire 170 may be omitted according to an alternative embodiment. A plurality of the wire 170 may be disposed on an upper surface of the second transparent conductive layer 160, and arranged in a grid pattern in a plan view of the unit cell.

An exemplary embodiment of a method of manufacturing a solar cell, according to the invention is described with reference to FIG. 2 to FIG. 8.

FIG. 1 shows a unit cell of a solar cell. FIG. 2 to FIG. 8 shows an exemplary embodiment of a method of manufacturing a solar cell module including multiple unit cells of the solar cell. A method of forming the solar cell module including the multiple unit cells is illustrated since the solar cell module is produced in a simpler process if the solar cell module is produced as shown in FIG. 2 to FIG. 8.

FIGS. 2 to 8 are cross-sectional views showing sequentially processes of an exemplary embodiment of manufacturing a solar cell module including the unit cell shown in FIG. 1

A substrate 110 formed of an insulation material, such as glass, is prepared. A buffer layer 120, a metal layer 130, and a first transparent conductive layer 140 are sequentially disposed on an upper surface of the glass substrate 110, as shown in FIG. 2.

The disposing of the buffer layer 120, the metal layer 130, and the first transparent conductive layer 140 may include laminating the buffer layer 120, the metal layer 130, and the first transparent conductive layer 140 to the glass substrate 110.

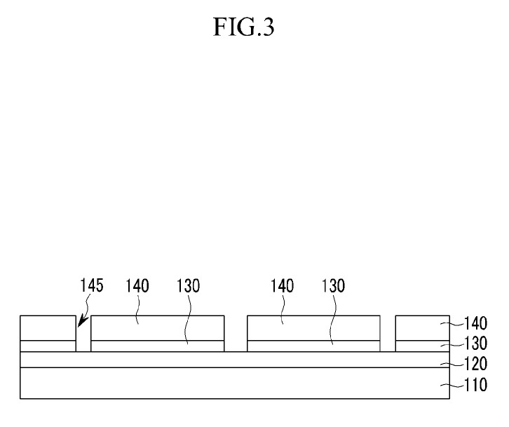

The metal layer 130 and the first transparent conductive layer 140 are patterned by scribing, such as using a laser scriber, as shown in FIG. 3. As a result of the patterning, a first gap 145 is provided in the metal layer 130 and the first transparent conductive layer 140. The first gap 145 extends completely through both the metal layer 130 and the first transparent conductive layer 140.

A plurality of the first gap 145 may be formed in the metal layer 130 and the first transparent conductive layer 140, as illustrated in FIG. 3. The plurality of the first gap 145 may be formed as substantially a same time, during the patterning of the metal layer 130 and the first transparent conductive layer 140.

In the patterning of the metal layer 130 and the first transparent conductive layer 140, the buffer layer 120 is not scribed. The buffer layer 120 is not scribed during the patterning of the metal layer 130 and the first transparent conductive layer 140 because the laser scriber does not scribe or transmit through the silicon oxide (SiO2), which is the material for forming the buffer layer 120. The laser is controlled to irradiate the desirable area to be etched using a laser scriber, and the laser may be irradiated from the upper or a lower side of the substrate 110 in FIG. 3.

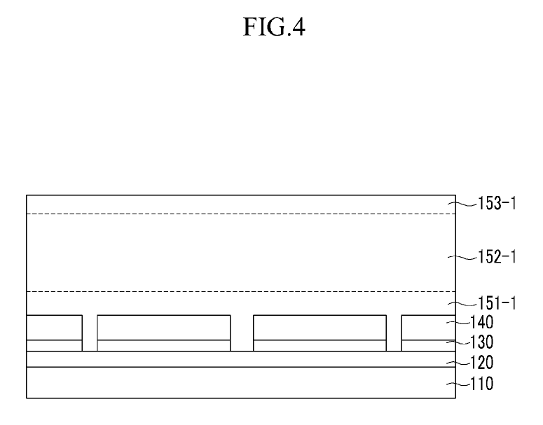

As shown in FIG. 4, an amorphous semiconductor layer 151-1 doped with the P-type impurities, a non-doped amorphous semiconductor layer 152-1, and an amorphous semiconductor layer 153-1 doped with N-type impurities are sequentially disposed on the substrate 110 including the buffer layer 120, the metal layer 130 and the first transparent conductive layer 140. Each amorphous semiconductor layer 151-1, 152-1, and 153-1 is laminated to each other, while a portion of the amorphous semiconductor layer 151-1 fills each of the first gap 145. In FIG. 4, a border (e.g., upper and lower surface) of each amorphous semiconductor layer 151-1, 152-1, and 153-1 is shown in parallel to the upper surface of substrate 110. In an alternative embodiment, the border of each amorphous semiconductor layer 151-1, 152-1, and 153-1 may include a border surface concavity extended toward an uppermost the surface of the first gap 145. An uppermost surface of the first gap 145 may be considered as a virtual surface (e.g., line) extending across the first gap 145, from a respective upper surface of the first transparent conductive layer 140 at edges of the first gap 145.

As shown in FIG. 4, the solar cell structure including the laminated amorphous semiconductor layer 151-1, 152-1, and 153-1, is crystallized without a separate seed layer.

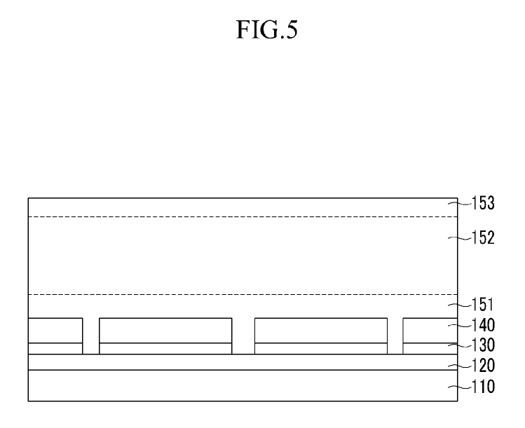

The crystallization is subjected to each amorphous semiconductor layer 151-1, 152-1, and 153-1 in FIG. 4. The amorphous semiconductor layers 151-1, 152-1, and 153-1 are respectively crystallized into a first polycrystalline semiconductor layer 151 doped with P-type impurities at a high concentration, a second polycrystalline semiconductor layer 152 doped with P-type impurities at a low concentration, and a third polycrystalline semiconductor layer 153 doped with N-type impurities at a high concentration, illustrated in FIG. 5 with a dotted line virtual border respectively indicated therebetween.

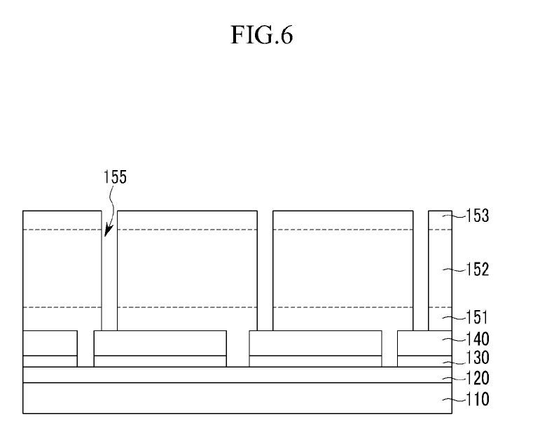

The first, second and third polycrystalline semiconductors 151, 152, and 153 are scribed, to include a second gap 155, such as using a laser scriber, as shown in FIG. 6. As a result, a first portion of an upper surface of the first transparent conductive layer 140 is exposed through the second gap 155. The second gap 155 extends completely through each of the first, second and third polycrystalline semiconductors 151, 152, and 153. A plurality of the second gap 155 may be formed in the first, second and third polycrystalline semiconductors 151, 152, and 153 as illustrated in FIG. 6. The plurality of the second gap 155 may be formed as substantially a same time, during the patterning of the first, second and third polycrystalline semiconductors 151, 152, and 153.

The metal layer 130 forms a reflecting layer of the solar cell structure, on a side of the first, second and third polycrystalline semiconductors 151, 152, and 153 opposite to the side from which light is incident thereon.

The first transparent conductive layer 140 exposed through the second gap 155 is exposed to form a contact of the solar cell module. The second gap 145 may not be overlapped with the first gap 145 of the metal layer 130 and the first transparent conductive layer 140. In an alternative embodiment, an upper surface of the metal layer 130 may be exposed through the second gap 155 formed by patterning the first, second and third polycrystalline semiconductors 151, 152, and 153. The laser is controlled to irradiate to the desirable area to be scribed using a laser scriber. FIG. 6 shows that the laser is irradiated from an upper side of the substrate 110, the first, second and third polycrystalline semiconductors 151, 152, and 153 being disposed on the upper side.

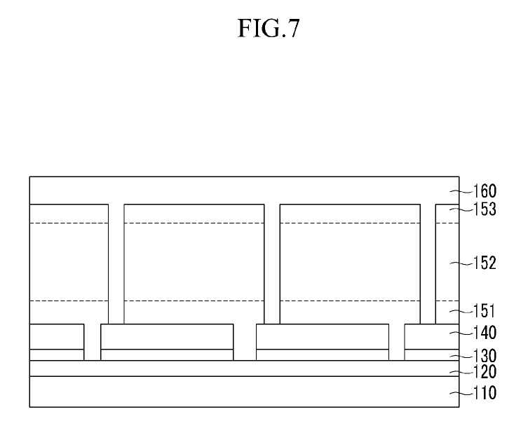

As shown in FIG. 7, the second transparent conductive layer 160 is disposed on the substrate 110 including the first, second and third polycrystalline semiconductors 151, 152, and 153, such as by lamination. The second transparent conductive layer 160 may be laminated after an antireflection treatment, or the second transparent layer 160 may be subjected to the antireflection treatment after the lamination to the first, second and third polycrystalline semiconductors 151, 152, and 153.

The second transparent conductive layer 160 is laminated to the first, second and third polycrystalline semiconductors 151, 152, and 153 and completely fills the second gap 155. As the result, the first transparent conductive layer 140 is electrically connected with the second transparent conductive layer 160, to include a structure in which one side electrode of the unit cell is electrically connected to another side electrode of an adjacent unit cell.

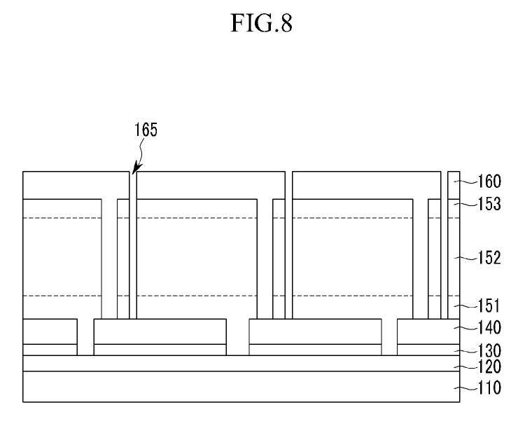

As shown in FIG. 8, the second transparent conductive layer 160 and the first, second and third polycrystalline semiconductors 151, 152, and 153 are scribed to provide a third gap 165, so a second portion of the upper surface of first transparent conductive layer 140 is exposed through the third gap 165. The third gap 165 partitions each unit cell of the solar cell, and is not overlapped with the first and second gaps 145 and 155, in a plan view of the unit cell. The laser is controlled to be irradiated to the desirable area to be scribed using a laser scriber. As shown in FIG. 8, the laser is irradiated from the upper side of the substrate 110.

The third gap 165 extends completely through the second transparent conductive layer 160 and each of the first, second and third polycrystalline semiconductors 151, 152, and 153. A plurality of the third gap 165 may be formed in the second transparent conductive layer 160 and the first, second and third polycrystalline semiconductors 151, 152, and 153 as illustrated in FIG. 8. The plurality of the third gap 165 may be formed as substantially a same time, during the patterning of the second transparent conductive layer 160 and the first, second and third polycrystalline semiconductors 151, 152, and 153.

As stated above, each unit cell of the solar cell is partitioned to electrically connect the second transparent conductive layer 160 of a first unit cell to the first transparent conductive layer 140 of a second (e.g., adjacent) unit cell, thereby coupling the adjacent unit cells of the solar cell in series, to provide a solar cell module. Referring to FIG. 8, boundaries of a unit cell may be defined by left or right edges of the third gap 165. Since the second transparent conductive layer 160 within one unit cell, is electrically connected to a first transparent conductive layer 140 overlapping both the one unit cell, and a unit cell adjacent to the one unit cell, the adjacent unit cells are connected in series.

A plurality of the unit cell of the solar cell, according to the embodiment shown in FIG. 1, may collectively form a solar cell module, and the plurality of the unit cell may be connected between the first and second transparent electrodes 140 and 160 of adjacent unit cells, respective, without providing the wire 170 shown in FIG. 1 to each unit cell. Thereby, a process of forming a solar cell module, including multiple unit cells, is simplified.

The method of manufacturing a unit cell of solar cell, and a solar cell module has been described in detail with reference to FIG. 1 to FIG. 8.

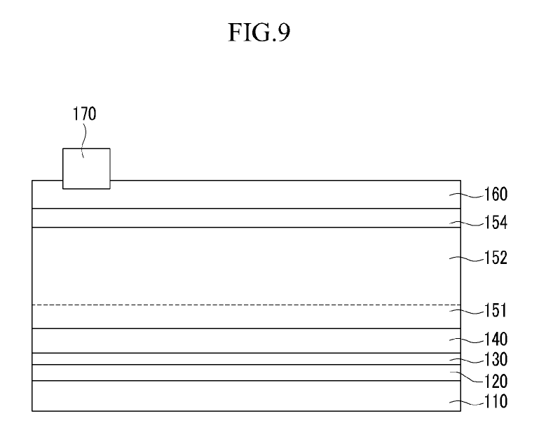

Hereinafter, another exemplary embodiment of a method of manufacturing a unit cell of a solar cell, and a solar cell module including crystallizing using a seed layer with reference of FIG. 9 to FIG. 17, will be described.

A portion of a solar cell, according to another exemplary embodiment of the invention is described with reference to FIG. 9.

FIG. 9 is a cross-sectional view of another exemplary embodiment of a unit cell of a solar cell, according to the invention.

The solar cell according to the exemplary embodiment shown in FIG. 9 generates electrical energy using the incident light from the upper side of the substrate 110.

Referring to FIG. 9, the solar cell forms a unit cell of solar cell by laminating a plurality of layers on a substrate 110 including an insulating material such as glass.

A silicon oxide (SiO₂) buffer layer 120 is disposed on the glass substrate 110. According to an exemplary embodiment, the buffer layer 120 includes silicon nitride (SiNx). The buffer layer 120 is a layer which prevents the diffusion of impurities from the glass substrate 110 when the amorphous silicon is crystallized. In addition, the buffer layer 120 is a layer which decreases the heat energy during transfer of the heat energy generated by crystallizing amorphous silicon to the glass substrate 110, so as to reduce damage to the glass substrate 110.

A metal layer 130 including metal is disposed on the buffer layer 120. The metal layer 130 blocks light even if the light is incident from the back surface of the glass substrate 110. In addition, the incident light from the upper side of the metal layer 130 is reflected and returned to the polycrystalline silicon disposed on the metal layer 130, so as to improve the efficiency of the solar cell. The metal layer 130 may be subjected to a surface texturing treatment to include various surface structures, such as a pyramid structure including protrusions and depressions, in order to diffuse the incident light from the upper side and induce the light into the polycrystalline silicon disposed on the metal layer 130. The metal layer 130 may include chromium (Cr), tungsten (W), molybdenum (Mo), and so on.

The first transparent conductive layer 140 including transparent zinc oxide (ZnO) having electrical conductivity may be disposed on the metal layer 130. According to an exemplary embodiment of the invention, the first transparent conductive layer 140 includes zinc oxide (ZnO), but the first transparent conductive layer 140 may include another transparent material having electrical conductivity.

The metal layer 130 and the first transparent conductive layer 140 form a side electrode of the unit cell of the solar cell, so a contact connecting to the outside may be connected to either the metal layer 130 or the first transparent conductive layer 140.

In addition, the first transparent conductive layer 140 may assist the metal layer 130 in reflecting the incident light from the upper side of the substrate 110. That is, the first transparent layer 140 may be subjected to a surface texturing treatment to include the various surfaces, such as a pyramid structure including protrusions and depressions, to diffuse the reflected light into the metal layer and to induce the light into the polycrystalline silicon disposed on the metal layer 130.

Semiconductors 151, 152, and 154 are disposed on the first transparent conductive layer 140. The semiconductors 151, 152, and 154 include a first polycrystalline semiconductor layer 151 doped with P-type impurities at a high concentration, a second polycrystalline semiconductor layer 152 doped with P-type impurities at a low concentration, and a third amorphous semiconductor layer 154 doped with N-type impurities at a high concentration. The second polycrystalline semiconductor layer 152 functions as a photo-absorptive layer, and electrical energy is generated by transferring electrons or holes generated by absorbing light into the first and third semiconductor layers 151 and 154.

The third amorphous semiconductor layer 154 of the solar cell may be formed by merely laminating (e.g., not crystallizing) an amorphous semiconductor layer doped with N-type impurities at a high concentration, and may have a total thickness of several tens of nanometers (nm). The P-type impurities may include Group III compounds such as boron (B), and the N-type impurities may include Group V compounds such as phosphorous (P).

In an alternative exemplary embodiment, the first and second polycrystalline semiconductor layers 151 and 152 may be polycrystalline semiconductor layers including N-type impurities. In this alternative embodiment, the impurities included in the third amorphous semiconductor layer 154 may be P-type impurities.

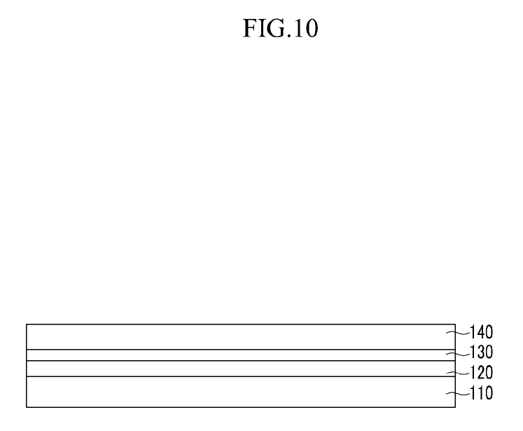

According to the embodiment shown in FIG. 9, the first polycrystalline semiconductor 151 may be used as a seed layer, different from the embodiment in FIG. 1 where the first, second and third polycrystalline semiconductors 151, 152, and 153 are formed without a seed layer. In an alternative embodiment, the second polycrystalline semiconductor 152 is formed (e.g., laminated) on the seed layer of the first polycrystalline semiconductor 151 in accordance with an epitaxy method, to provide a second polycrystalline semiconductor layer 152. Hereinafter, a method of manufacturing a solar cell including the unit cell of FIG. 9 is described with reference to FIG. 10 to FIG. 17.

Referring again to FIG. 9, the second transparent conductive layer 160 is disposed on an uppermost surface of the first, second and third semiconductors 151, 152, and 154. The second transparent conductive layer 160 functions as a side electrode of the unit cell of the solar cell, as being electrically and physically connected to the metal layer 130 and the first transparent conductive layer 140. In addition, the second transparent conductive layer 160 may be subjected to the antireflection treatment to improve the efficiency of the incident light from the upper side of the substrate 110. The second transparent conductive layer 160 may include the transparent conductive material having high electrical conductivity. In an exemplary embodiment, the second transparent conductive layer 160 may include ITO, ZnO, IZO, and so on.

A wire 170 including metal such as silver, may be disposed on one region of the second transparent conductive layer 160. In alternative embodiments, the wire 170 may be omitted, or a plurality of wires 170 may be disposed on the upper surface of the second transparent conductive layer 160 in a grid pattern in a plan view of the solar cell.

An exemplary embodiment of a method of manufacturing a solar cell according to the invention is described hereinafter with reference to FIG. 10 to FIG. 17.

FIG. 9 shows a single unit cell of a solar cell. FIG. 10 to FIG. 17 shows another exemplary embodiment of a method of manufacturing a solar cell module including multiple unit cells of the solar cell. A method of forming the solar cell module including the multiple unit cell is illustrated because it is possible to produce a solar cell module in a lesser number of processes when the solar cell module is produced as shown in FIG. 10 to FIG. 17.

FIGS. 10 to 17 are cross-sectional views showing sequentially processes of an exemplary embodiment of manufacturing a solar cell module including the unit cell shown in FIG. 9.

A substrate 110 including an insulating material, such as glass, is prepared. A buffer layer 120, a metal layer 130, and a first transparent conductive layer 140 are sequentially laminated on an upper surface of the glass substrate 110, as shown in FIG. 10.

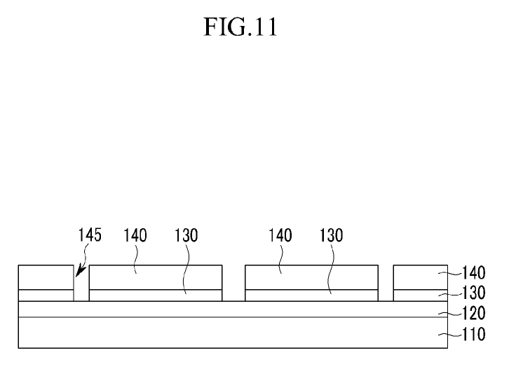

The metal layer 130 and the first transparent conductive layer 140 are scribed and patterned using a laser scriber, as shown in FIG. 11. As a result of the patterning, a first gap 145 is provided in the metal layer 130 and the first transparent conductive layer 140. The buffer layer 120 is not scribed. The buffer layer 120 is not etched because the laser scriber does not scribe or transmit through the silicon oxide SiO2, which is a material for forming the buffer layer 120. It is possible to control to irradiate the laser to the desirable area to be scribed using a laser scriber, and the laser is irradiated from the upper or lower side of the substrate 110.

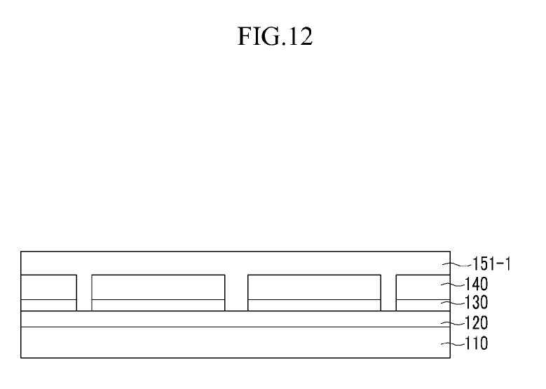

An amorphous semiconductor layer 151-1 doped with P-type impurities thereon is formed on the substrate 110 including the buffer layer 120, the metal layer 130 and the first transparent conductive layer 140. The amorphous semiconductor layer 151-1 is disposed to fill the first gap 145. Although the border (e.g., the upper surface) of the amorphous semiconductor layer 151-1 is shown to be parallel to the surface of the substrate 110 in FIG. 12, the border may include a portion being a concave surface protruded toward the substrate 110, and overlapping the first gap 145 in a plan view of the solar cell.

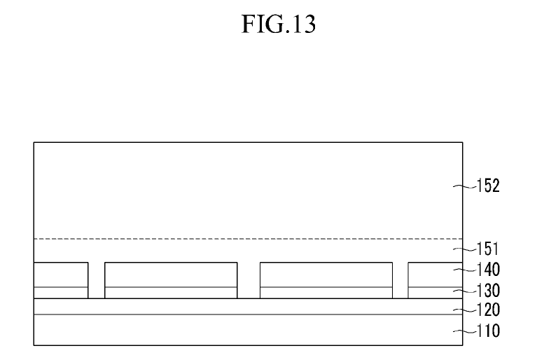

The amorphous semiconductor layer 151-1 doped with P-type impurities is subjected to crystallization. As shown in FIG. 12, the solar cell including the unit cell shown in FIG. 9, is subjected to the crystallization by developing the amorphous semiconductor layer 151-1 doped with P-type impurities as a seed layer. Through the crystallization, the amorphous semiconductor layer 151-1 forms a first polycrystalline semiconductor layer 151 doped with P-type impurities at a high concentration. A non-doped semiconductor layer is developed on the seed layer of the first polycrystalline semiconductor 151 in accordance with an epitaxy method, to provide a second polycrystalline semiconductor layer 152 doped with P-type impurities at a low concentration, as shown in FIG. 13 with a dotted line virtual border indicated therebetween. After the crystallization, a hydrogenising process may be performed on the resulting structure including the first polycrystalline semiconductor 151 and the second polycrystalline semiconductor layer 152, in another exemplary embodiment of the invention.

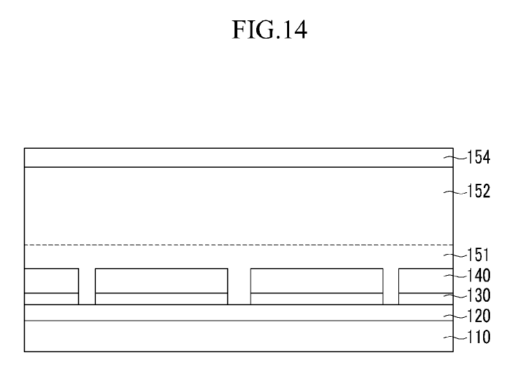

An amorphous semiconductor layer doped with N-type impurities at a high concentration is laminated to provide a third amorphous semiconductor layer 154, as shown in FIG. 14 with a solid line virtual border indicated between the third amorphous semiconductor layer 154 and the second polycrystalline semiconductor layer 152. The first polycrystalline semiconductor layer 151, the second polycrystalline semiconductor layer 152 and the third amorphous semiconductor layer 154 collectively form a structure including two polycrystalline semiconductor layers doped with one layer of impurities.

The metal layer 130 forms a reflecting layer of the solar cell structure, on a side of the first polycrystalline semiconductor layer 151, the second polycrystalline semiconductor layer 152 and the third amorphous semiconductor layer 154 opposite to the side from which light is incident thereon.

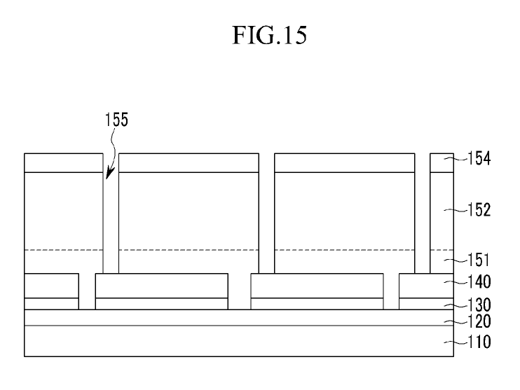

Then semiconductors 151, 152, and 154 are scribed using a laser scriber, to provide a second gap 155 resulting in exposure of a first portion of an upper surface of the first transparent conductive layer 140, as shown in FIG. 15. The first transparent conductive layer 140 exposed through the second gap 155 is exposed to provide a contact portion. The second gap 155 may not be overlapped with the first gap 145 in the plan view of the solar cell. In an alternative embodiment, the surface of metal layer 130 may be exposed through the second gap 155 formed by patterning the first, second and third semiconductors 151, 152, and 154. It is possible to control the laser to irradiate to the desirable area to be etched using a laser scriber. The laser may be irradiated from an upper side of substrate 110, as shown in FIG. 15.

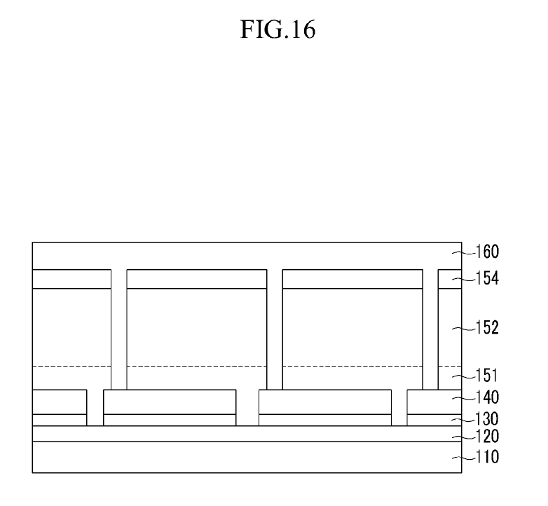

A second transparent conductive layer 160 is laminated on the substrate 110 including the first, second and third polycrystalline semiconductors 151, 152, and 154, as shown in FIG. 16. The second transparent conductive layer 160 is laminated to the substrate 110 after being subjected to the antireflection treatment, or is subjected to the antireflection after the lamination to the substrate.

The second transparent conductive layer 160 is laminated to the substrate and completely fills the second gap 155. As the result, the first transparent conductive layer 140 and the second transparent conductive layer 160 are electrically connected to each other, to include a structure in which one side electrode of each unit cell is electrically connected to a side electrode of another (adjacent) unit cell.

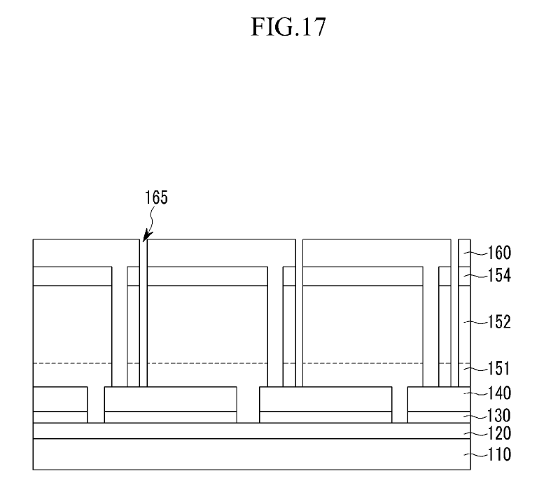

The second transparent conductive layer 160 and semiconductors 151, 152, and 154 are scribed to provide a third gap 165, using a laser scriber, as shown in FIG. 17. Thereby, a second portion of the upper surface of first transparent conductive layer 140 is exposed. The third gap 165 partitions each unit cell of the solar cell, and is not overlapped with the first and second gaps 145 and 155 in the plan view of the solar cell. Using the laser scriber, it is possible to control to irradiate the laser to the desirable area to be etched. The laser is irradiated from the upper side of the substrate 110 in FIG. 17.

As described above, each unit cell of the solar cell is partitioned to electrically connect the second transparent conductive layer 160 to the first transparent conductive layer 140, and unit cells of the solar cell are coupled in series to provide a solar cell module.

As in the above-mentioned method, a plurality of the unit cell of the solar cell according to the embodiment shown in FIG. 9, may collectively form a solar cell module.

The forming of the solar cell module including the plurality of the unit cell of FIG. 9, has merits of decreasing the number of processes, since the electrodes of adjacent unit cells are connected without providing the wire 170 shown in FIG. 9.

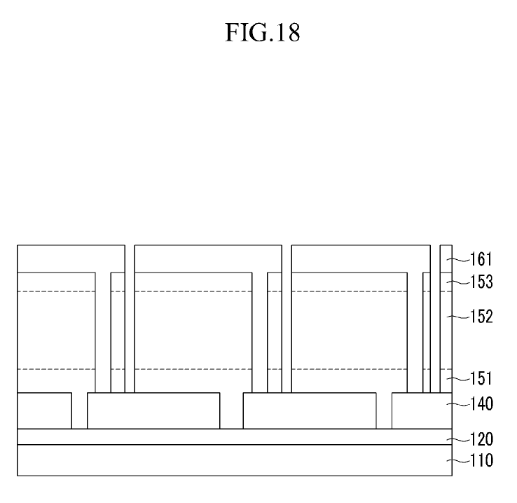

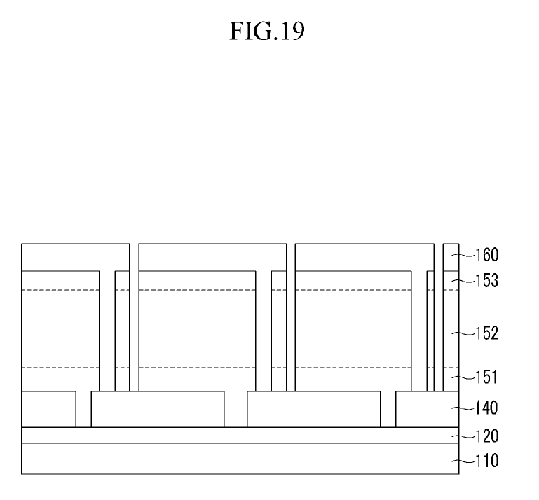

In the above illustrated embodiments, a solar cell generating electrical energy using the incident solar light from the upper side of the substrate 110 with reference to FIG. 1 to FIG. 8, and FIG. 9 to FIG. 17, has been described. Referring to FIGS. 18 and 19, hereinafter, a solar cell module structure (FIG. 18) using the incident solar light from the back (e.g., lower) surface of the substrate 110 and a solar cell module structure (FIG. 19) using the incident solar light from both upper and lower surfaces of the substrate 110 will be described in detail.

FIG. 18 is a cross-sectional view of another exemplary embodiment of a solar cell module, according to the invention. FIG. 18 shows a solar cell module using solar light incident from the back (e.g., bottom of the view in FIG. 18) surface of the substrate 110.

To utilize the solar light incident from the lower surface of the substrate 110, a reflective metal layer 161 is disposed to form an uppermost layer of the solar cell module, instead of uppermost layer being the second transparent conductive layer 160. Additionally, a metal layer 130 is not included in the solar cell module, different from the solar cell shown in FIG. 1 to FIG. 17.

Referring to FIG. 18, the solar cell according to the illustrated embodiment includes a buffer layer 120 including silicon oxide (SiO2), disposed on an upper surface of the substrate 110 including an insulation material, such as glass. In an alternative embodiment, the buffer layer 120 may be formed of silicon nitride (SiNx). The buffer layer 120 is a layer which reduces or effectively prevents the diffusion of impurities from the glass substrate 110 when the amorphous silicon is crystallized during a manufacturing process. In addition, the buffer layer 120 decreases the heat energy while transferring the heat energy generated by crystallizing the amorphous silicon into the glass substrate 110, so as to reduce damage to the glass substrate 110. The buffer layer 120 may be subjected to the antireflection treatment, so the incident light from the back surface of the substrate 110 is not reflected, so as to not decrease the efficiency of the solar cell module.

A first transparent conductive layer 140 including zinc oxide (ZnO) having electrical conductivity may be disposed directly on the buffer layer 120. The first transparent conductive layer 140 may include a transparent conductive material such as ITO or IZO as well as zinc oxide. Where the first transparent conductive layer 140 may include zinc oxide (ZnO), the first transparent conductive layer 140 may include another transparent material having electrical conductivity, according to an alternative embodiment of the invention. The first transparent conductive layer 140 functions as one side electrode of the unit cell of the solar cell.

Polycrystalline semiconductors 151, 152, and 153 are disposed on a first transparent conductive layer 140. The polycrystalline semiconductors 151, 152, 153 include a first polycrystalline semiconductor layer 151 doped with P-type impurities at a high concentration, a second polycrystalline semiconductor layer 152 doped with P-type impurities at a low concentration, and a third amorphous semiconductor layer 153 doped with N-type impurities at a high concentration. The second polycrystalline semiconductor layer 152 functions as a photo-absorptive layer, and generates electrical energy by transferring electrons or holes generated by absorbing the light into the first and third polycrystalline semiconductor layers 151 and 153.

The P-type impurities may be Group III compounds such as boron (B), and the N-type impurities may be Group V compounds such as phosphorous (P). FIG. 18 shows that the first, second and third polycrystalline semiconductor layers 151, 152 and 153 are laminated as in the embodiment shown in FIG. 1 with a dotted line virtual border respectively indicated therebetween, but the solar module may include a structure including one impurity-doped amorphous semiconductor layer on two polycrystalline semiconductor layers as illustrated in FIG. 9 to FIG. 17.

A reflective metal layer 161 is disposed directly on an uppermost surface of the first, second and third polycrystalline semiconductors 151, 152, and 153. The reflective metal layer forms a reflecting layer of the solar cell structure, on a side of the first, second and third polycrystalline semiconductors 151, 152, and 153 opposite to the side from which light is incident thereon. The reflective metal layer 161 functions as a side electrode of the unit cell of the solar cell, as being electrically and physically connected to the first transparent conductive layer 140. The reflective metal layer 161 may include chromium (Cr), tungsten (W), molybdenum (Mo), aluminum (Al), silver (Ag), and the like.

In addition, a reflective transparent conductive layer (not shown) may be provided between the reflective metal layer 161 and the uppermost surface of the first, second and third polycrystalline semiconductors 151, 152 and 153. The reflective transparent conductive layer may be treated with a surface texturing treatment to provide various surface structures, such as a pyramid structure including protrusions and depressions on one side surface thereof, so as to assist the reflective metal layer 161 in reflecting the incident light from the back side of the substrate, and to improve the efficiency of the incident light from the back surface of the substrate 110. According to an exemplary embodiment, the reflective transparent conductive layer may include a transparent conductive material having high electrical conductivity. The reflective transparent conductive layer may include ITO, ZnO, IZO, and so on.

The reflective metal layer 161 is electrically connected to the first transparent conductive layer 140, so the unit cells of the solar cell are coupled in series to provide a module.

In contrast, FIG. 19 shows a solar cell module structure using the incident solar light from both surfaces of the substrate 110, e.g., from a front side and a back side of the solar cell module.

To utilize the solar light incident from the lower surface and the lower surface of the substrate 110, a metal layer 130 is not included within the solar cell structure, different from the solar cell shown in FIG. 1 to FIG. 17.

FIG. 19 is a cross-sectional view of another exemplary embodiment of a solar cell module, according to the invention.

Referring to FIG. 19, the solar cell according to the illustrated embodiment includes a buffer layer 120 including silicon oxide (SiO2) on a substrate 110 including an insulation material, such as glass. In an alternative embodiment, the buffer layer 120 may include silicon nitride (SiNx). The buffer layer 120 is a layer which reduces or effectively prevents the diffusion of impurities from the glass substrate 110 when the amorphous silicon is crystallized during a manufacturing process. In addition, the buffer layer 120 decreases the heat energy while transferring the heat energy generated by crystallizing the amorphous silicon into the glass substrate 110, so as to reduce damage to the glass substrate 110. The buffer layer 120 may be subjected to the antireflection treatment, so the incident light from the back surface of the substrate 110 is not reflected so as to not decrease the efficiency of the solar cell module.

A first transparent conductive layer 140 including zinc oxide (ZnO) having electrical conductivity may be disposed directly on the buffer layer 120. The first transparent conductive layer 140 may include zinc oxide (ZnO), but the first transparent conductive layer 140 may include another transparent material having electrical conductivity according to an alternative embodiment of the invention. The first transparent conductive layer 140 functions as one side electrode of the solar cell unit cell.

Polycrystalline semiconductors 151, 152, and 153 are disposed on the first transparent conductive layer 140. The polycrystalline semiconductors 151, 152, and 153 include a first polycrystalline semiconductor layer 151 doped with P-type impurities at a high concentration, a second polycrystalline semiconductor layer 152 doped with P-type impurities at a low concentration, and a third amorphous semiconductor layer 153 doped with N-type impurities at a high concentration. The second polycrystalline semiconductor layer 152 functions as a photo-absorptive layer, and generates electrical energy by transferring electrons or holes generated by absorbing light into the first and third polycrystalline semiconductor layers 151 and 153.

The P-type impurities may be Group III compounds such as boron (B), and the N-type impurities may be Group V compounds such as phosphorous (P). FIG. 19 shows that three polycrystalline semiconductor layers are laminated as in the embodiment shown in FIG. 1, but the solar cell module may include a structure including two polycrystalline semiconductor layers doped with one layer of impurities as in the embodiment shown in FIG. 9.

A second transparent conductive layer 160 is disposed directly on an uppermost surface of the first, second and third polycrystalline semiconductors 151, 152, and 153. The second transparent conductive layer 160 functions as one side electrode of the unit cell of the solar cell, as being electrically and physically connected to the first transparent conductive layer 140. In addition, the second transparent conductive layer 160 may be subjected to an antireflection treatment in order to improve the efficiency of the incident light from the upper side of the solar cell structure. According to an exemplary embodiment, the second transparent conductive layer 160 may include a transparent conductive material having high electrical conductivity. The second transparent conductive layer may include ITO, ZnO, IZO, and so on.

In the solar cell module structure using the incident solar light from both sides of the solar cell module, a reflecting layer is effectively not formed.

The second transparent conductive layer 160 is electrically connected to a first transparent conductive layer 140, so unit cells of the solar cell are coupled in series to provide a solar cell module.

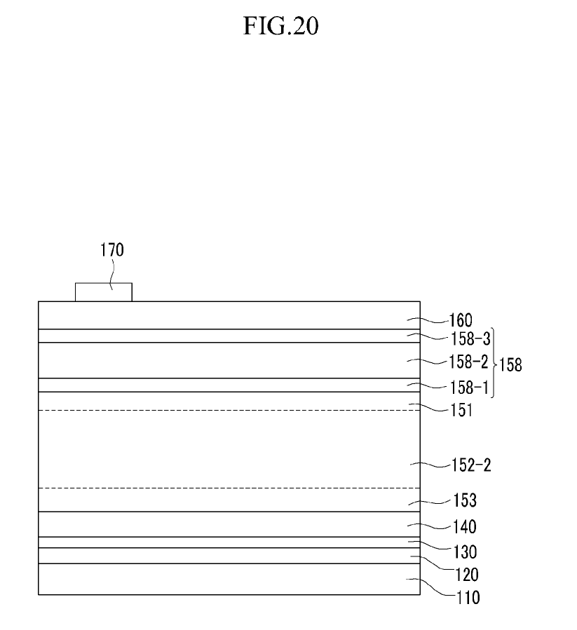

Hereinafter, another exemplary embodiment of a unit cell of a solar cell module is described with reference to FIG. 20.

FIG. 20 is a cross-sectional view of another exemplary embodiment of a unit cell of a solar cell module, according to the invention.

The embodiment shown in FIG. 20 includes a tandem structure in which a semiconductor part absorbing light is overlapped. In addition, N-type impurities are doped on lower layers of the semiconductor layer, and P-type impurities are doped on upper layers, differing from the embodiment shown in FIG. 1 and FIG. 8.

Referring to FIG. 20, according to the exemplary embodiment, a buffer layer 120 including silicon oxide (SiO2) is disposed on the substrate 110 including an insulation material, such as glass. In an alternative embodiment, the buffer layer 120 may include silicon nitride (SiNx). The buffer layer 120 is a layer which reduces or effectively prevents the diffusion of impurities from the glass substrate 110 when the amorphous silicon is crystallized during a manufacturing process. In addition, the buffer layer 120 decreases the heat energy while transferring the heat energy generated by crystallizing the amorphous silicon into the glass substrate 110, so as to reduce damage to the glass substrate 110.

A metal layer 130 including metal is disposed directly on a buffer layer 120. The metal layer 130 blocks light even if the light is incident from the back surface of the glass substrate 110. In addition, the incident light from the upper side of the metal layer 130 is reflected and returned into the polycrystalline silicon disposed on the metal layer 130, thereby improving efficiency of the solar cell. The metal layer 130 may be subjected to a surface texturing treatment to include various surface structures such as a pyramid structure including protrusions and depressions, in order to diffuse the incident light from the upper side of the solar cell and induce the light into the polycrystalline silicon. The metal layer 130 may include chromium (Cr), tungsten (W), molybdenum (Mo), and so on.

The first transparent conductive layer 140 including transparent zinc oxide (ZnO) having electrical conductivity may be disposed directly on the metal layer 130. In the illustrated embodiment, the first transparent conductive layer 140 is includes zinc oxide (ZnO), but the first transparent conductive layer 140 may include a transparent material (ITO, IZO) having high electrical conductivity.

The metal layer 130 and the first transparent conductive layer 140 function as one side electrode of the unit cell of the solar cell, so the contact of the solar cell connecting to the outside of the solar cell may be connected to either the metal layer 130 or the first transparent conductive layer 140.

In addition, the first transparent conductive layer 140 may assist the metal layer 130 in reflecting the incident light from the upper side of the solar cell. The first transparent conductive layer 140 may be subjected to a surface texturing treatment to provide the various surfaces such as the pyramid structure including protrusions and depressions, so as to diffuse the reflected light into the metal layer 130 and induce the light into the polycrystalline silicon.

Polycrystalline semiconductors (153, 152-2, 151) are disposed on the first transparent conductive layer 140. The polycrystalline semiconductors (153, 152-2, 151) include a polycrystalline semiconductor layer 153 doped with N-type impurities at a high concentration, a polycrystalline semiconductor layer 152-2 doped with N-type impurities at a low concentration, and a polycrystalline semiconductor layer 151 doped with P-type impurities at a high concentration. The polycrystalline semiconductor layer 152-2 functions as the photo-absorptive layer of the solar cell, and generates electrical energy by transferring electrons or holes generated by absorbing light into the polycrystalline semiconductor layers 151 and 153 doped with impurities at a high concentration.

The P-type impurities may be Group III compounds such as boron (B), and the N-type impurities may be Group V compounds such as phosphorous (P). FIG. 20 shows that a three-layered polycrystalline semiconductor layer (153, 152-2, 151) is laminated as in the embodiment shown in FIG. 1, but the semiconductor layer may include a structure including an amorphous semiconductor layer in which one-layered impurities are doped on two polycrystalline semiconductor layers as in the embodiment shown in FIG. 9.

An auxiliary photo-absorptive layer 158 is disposed on an uppermost surface of the collective polycrystalline semiconductors 153, 152-2 and 151. The auxiliary photo-absorptive layer 158 includes a first amorphous semiconductor layer 158-1 doped with N-type impurities disposed directly on the uppermost surface of the collective polycrystalline semiconductors 153, 152-2 and 151, a non-doped second amorphous semiconductor layer 158-2, and a third amorphous semiconductor layer 158-3 doped with P-type impurities. The first amorphous semiconductor layer 158-1 doped with N-type impurities is directly laminated on and disposed directly adjacent to a polycrystalline semiconductor layer 151 doped with P-type impurities at a high concentration. The second amorphous semiconductor layer 158-2 and the third amorphous semiconductor layer 158-3 are sequentially laminated thereon towards the upper side of the unit cell.

In an alternative embodiment, when a polycrystalline semiconductor layer doped with P-type impurities at a high concentration, a polycrystalline semiconductor layer doped with P-type impurities at a low concentration, and a polycrystalline amorphous semiconductor layer doped with N-type impurities at a high concentration are sequentially laminated (FIG. 1) in a direction away from the substrate 110, the auxiliary photo-absorptive layer 158 may be formed by sequentially laminating an amorphous semiconductor layer 158-3 doped with P-type impurities, an amorphous semiconductor layer 158-2, and an amorphous semiconductor layer 158-1 doped with N-type impurities. The amorphous semiconductor layer 158-3 doped with P-type impurities would then be disposed directly on and adjacent to the polycrystalline amorphous semiconductor layer doped with N-type impurities at a high concentration.

The auxiliary photo-absorptive layer 158 assists the polycrystalline semiconductors (153, 152-2, 151) to generate electrical energy by absorbing light. Thereby, the auxiliary photo-absorptive layer 158 improves the efficiency of absorbing light.

A second transparent conductive layer 160 is disposed directly on the auxiliary photo-absorptive layer 158. The second transparent conductive layer 160 functions as one side electrode of the unit cell of the solar cell, as being electrically and physically connected to the metal layer 130 and the first transparent conductive layer 140. In addition, the second transparent conductive layer 160 is subjected to an antireflection treatment in order to improve the efficiency of light incident from the upper side of the unit cell of the solar cell. According to an exemplary embodiment, the second transparent conductive layer 160 may include a material having high electrical conductivity. The second transparent conductive layer 160 may include ITO, ZnO, IZO, and so on.

A wire 170 including metal such as silver may be disposed directly on an upper surface and in one region of the second transparent conductive layer 160. The wire 170 may be omitted in an alternative exemplary embodiment, and a plurality of the wire 170 may be disposed on the upper surface of the second transparent conductive layer 160, such as in a grid pattern.

While this disclosure has been described in connection with what is presently considered to be practical exemplary embodiments, it is to be understood that the invention is not limited to the disclosed embodiments, but, on the contrary, is intended to cover various modifications and equivalent arrangements included within the spirit and scope of the appended claims.

What is claimed is:

1. A solar cell comprising:
an insulation substrate;
a buffer layer disposed on the insulation substrate;
a first electrode disposed on the buffer layer;
a first polycrystalline semiconductor layer disposed on the first electrode and comprising a first impurity;
a photo-absorptive layer disposed on the first polycrystalline semiconductor layer;
a second semiconductor layer disposed on the photo-absorptive layer and comprising a second impurity; and
a second electrode disposed on the second semiconductor layer.

2. The solar cell of claim 1, wherein
the first polycrystalline semiconductor layer is a polycrystalline silicon doped with the first impurity at a high concentration, and
the photo-absorptive layer is polycrystalline silicon doped with the first impurity at a low concentration.

3. The solar cell of claim 2, wherein the second semiconductor layer is a polycrystalline silicon comprising the second impurity.

4. The solar cell of claim 2, wherein the second semiconductor layer is an amorphous silicon comprising the second impurity.

5. The solar cell of claim 1, wherein at least one of the first electrode and the second electrode comprises a transparent conductive material.

6. The solar cell of claim 5, further comprising a metal layer disposed between the buffer layer and the first electrode, wherein the second electrode comprises a transparent conductive material.

7. The solar cell of claim 6, wherein the metal layer comprises chromium, tungsten, or molybdenum.

8. The solar cell of claim 6, wherein the transparent conductive material includes zinc oxide, indium tin oxide, or indium zinc oxide.

9. The solar cell of claim 6, wherein
the metal layer or the first electrode comprises surface structures including protrusions and depressions, or
the second electrode comprises an antireflection treatment.

10. The solar cell of claim 5, wherein the second electrode comprises an opaque metal.

11. The solar cell of claim 10, wherein the opaque metal comprises chromium, tungsten, molybdenum, silver, or aluminum.

12. The solar cell of claim 10, wherein
the second electrode comprises a pyramid structure including protrusions and depressions, or
the buffer layer comprises an antireflection treatment.

13. The solar cell of claim 1, further comprising an auxiliary photo-absorptive layer between the second semiconductor layer and the second electrode,
wherein the auxiliary photo-absorptive layer comprises an amorphous silicon layer comprising the first impurity, a non-doped amorphous silicon layer, and an amorphous silicon layer comprising the second impurity.

14. The solar cell of claim 1, wherein the buffer layer includes silicon oxide or silicon nitride.

15. A method of manufacturing unit cells of a solar cell comprising:
providing a buffer layer on an insulation substrate;
providing a first electrode on the buffer layer;
providing an amorphous semiconductor on the first electrode;
crystallizing the amorphous semiconductor; and
providing a second electrode on the crystallized semiconductor.

16. The method of claim 15, further comprising hydrogenising after crystallizing the amorphous semiconductor.

17. The method of claim 15, wherein the providing a first electrode comprises scribing the first electrode with a laser to provide a one side electrode forming an independent unit cell of the solar cell, and
the provided amorphous semiconductor is contacted with a region of the first electrode where the laser scribes the first electrode.

18. The method of claim 15, further comprising scribing the crystallized semiconductor with a laser to expose the first electrode,
wherein the providing a second electrode includes electrically contacting the second electrode with the exposed region of the first electrode.

19. The method of claim 15, further comprising scribing the second electrode and the crystallized semiconductor with a laser to electrically separate adjacent unit cells of the solar cell, after the providing a second electrode.

20. The method of claim 15, further comprising providing a metal layer between the buffer layer and the first electrode, wherein
the second electrode includes a transparent conductive material; and
the providing a second electrode further comprises subjecting the second electrode to an antireflection treatment, or
the providing a metal layer or the providing a first electrode comprises respectively subjecting the metal layer or the first electrode to a surface texturing treatment, to provide a structure including protrusions and depressions.

21. The method of claim 15, wherein the second electrode comprises an opaque metal, and
the providing a second electrode comprises subjecting the second electrode to a surface texturing treatment, to provide a structure including protrusions and depressions, or
the providing a buffer layer comprises subjecting the buffer layer to an antireflection treatment.

22. The method of claim 15, wherein the providing an amorphous semiconductor on the first electrode comprises:
providing a first amorphous silicon comprising a first impurity on the first electrode;
providing a non-doped second amorphous silicon on the first amorphous silicon; and
providing a third amorphous silicon comprising a second impurity on the second amorphous silicon.

23. The method of claim 15, wherein
the providing an amorphous semiconductor on the first electrode comprises:
providing a first amorphous silicon comprising a first impurity on the first electrode;
crystallizing the first amorphous silicon to provide a seed layer;
and forming a non-doped second silicon in accordance with an epitaxy method to provide a polycrystalline semiconductor.

24. The method of claim 23, further comprising laminating a third amorphous silicon comprising a second impurity on the polycrystalline semiconductor after crystallizing.

25. The method of claim 15, further comprising:
providing an auxiliary photo-absorptive layer on the crystallized semiconductor after crystallizing the amorphous semiconductor,
wherein the providing an auxiliary photo-absorptive layer comprises:
providing a fourth amorphous silicon layer comprising a first impurity on the crystallized semiconductor;
providing a non-doped fifth amorphous silicon layer on the fourth amorphous silicon layer; and
providing a sixth amorphous silicon layer comprising a second impurity on the fifth amorphous silicon layer.
